(19) United States
(12) Patent Application Publication
(10) Pub. No.: US 2019/0276946 A1
(43) Pub. Date: Sep. 12, 2019

(54) METHOD OF PRODUCING HIGH RESOLUTION MULTICOLORED LINE ART IMAGES VIA ANODIZATION OF REFRACTORY METALS

(71) Applicant: Paul FISCHER, Oakland, CA (US)

(72) Inventor: Paul FISCHER, Oakland, CA (US)

(21) Appl. No.: 15/918,524

(22) Filed: Mar. 12, 2018

(51) Int. Cl. C25D 11/26; C25D 11/02; C09D 11/101; C23C 16/48; C22C 32/00; C09D 5/44; C09D 11/30

(52) U.S. Cl. CPC C25D 11/26; C25D 11/024; C09D 11/101; C09D 11/30; C22C 32/0031; C09D 5/4484; C23C 16/48

(57) ABSTRACT

Methods for coloring metals, particularly refractory metals, via anodization is provided that utilizes UV-curable ink, which allows for color layer patterns with much higher spatial resolution that one can achieve with photoresist-based masks. The methods of the present invention can be used to create very detailed, high resolution multicolored line art images on refractory metals.

### BACKGROUND OF THE INVENTION

### 1. Field of the Invention

The present invention relates generally to a method of anodizing metals and, more particularly, to a method of coloring refractory metals via anodization that can be used to create high resolution multicolored line art images.

### 2. Background of the Related Art

Refractory metals, such as titanium, niobium, tantalum, hafnium and vanadium, can be colored by the formation of an oxide layer on the surface of the metal. The color seen by the human eye is created by optical interference, with the thickness of the oxide layer determining what color is seen.

The oxide layer is formed on the refractory metal via anodization using an electrical current. This is typically accomplished with a D.C. generator that can produce an electrical current at varying voltages. The refractory metal to be anodized is typically attached to the positive terminal, or anode, and another piece of metal, such as stainless steel, is attached to the negative terminal, or cathode. Both the refractory metal to be anodized and the piece of metal attached to the cathode are then suspended, without touching each other, in an electrolytic solution.

When a current is applied, oxygen is formed at the anode (the refractory metal to be colored). The oxygen combines with the refractory metal and forms an oxide layer on the refractory metal (hereinafter referred to as a “color layer”). The thickness of the oxide layer increases with increasing voltage.

When light hits the oxide layer, the reflected light will exhibit a particular color based on the thickness of the oxide layer as a result of optical interference effects. The thickness of the oxide layer determines the reflected color (the color perceived by the human eye). Thus, different colors are produced by different anodization voltages. As is well known in the art, the voltages needed to produce a specific color can vary depending on different factors, such as the surface area of the reactive metal being anodized. Hereinafter, an oxide layer grown on a refractory metal that generates a particular color via optical interference effects will be referred to as a “color layer.”

Photoresist masks have been used in this anodization process when one only wants to anodize predetermined portions of the metal. However, the spatial resolution that is achievable with photoresist masks is not ideal for creating high resolution colored line art images on refractory metals via anodization.

### SUMMARY OF THE INVENTION

An object of the invention is to solve at least the above problems and/or disadvantages and to provide at least the advantages described hereinafter.

Therefore, an object of the present invention is to provide a method of anodizing metals in a predetermined pattern.

Another object of the present invention is to provide a method of producing color layers on refractory metals in predetermined patterns via anodization.

Another object of the present invention is to provide a method of creating multicolored line art images on refractory metals via anodization.

Another object of the present invention is to provide a method of anodizing metals in a predetermined pattern using UV curable ink as a mask.

Another object of the present invention is to provide a method of producing color layers on refractory metals in a predetermined pattern via anodization using UV curable ink as a mask.

Another object of the present invention is to provide a method of producing multiple color layers on refractory metals in predetermined patterns via anodization in which the order in which color layers are anodized does not depend on the voltage requirements for each color layer.

Another object of the present invention is to provide a method of creating multicolored line art images on refractory metals via anodization using UV curable ink as a mask.

To achieve at least the above objects, in whole or in part, there is provided a method of creating at least two color layers on a refractory metal substrate (“substrate”), comprising applying a UV-cured ink layer to the substrate in a predetermined pattern corresponding to a desired pattern for a desired color layer, wherein the desired color layer requires a corresponding anodization voltage, (b) anodizing the substrate using the corresponding anodization voltage to create the desired color layer on the substrate;, (c) removing the UV-cured ink layer; (d) applying a subsequent UV-cured ink layer to the substrate in a predetermined pattern corresponding to a desired pattern for a subsequent desired color layer, wherein the subsequent desired color layer requires a subsequent corresponding anodization voltage that is lower than the anodization voltage used for the previous color layer, (e) anodizing the substrate using the subsequent corresponding anodization voltage, and (f) removing the second UV-cured ink layer.

To achieve at least the above objects, in whole or in part, there is also provided a A method of creating at least two color layers on a refractory metal substrate (“substrate”), comprising (a) applying a UV-cured ink layer to the substrate in a predetermined pattern corresponding to a desired pattern for a desired color layer, wherein the desired color layer requires a corresponding anodization voltage, (b) anodizing the substrate using the corresponding anodization voltage to create the desired color layer on the substrate, (c) removing the UV-cured ink layer, (d) applying a subsequent UV-cured ink layer to the substrate in a predetermined pattern corresponding to a desired pattern for a subsequent desired color layer, wherein the subsequent desired color layer requires a subsequent corresponding anodization voltage that is lower than the anodization voltage used for the previous color layer and wherein the subsequent UV-cured ink layer is also applied so as to cover the previously created color layer, (e) anodizing the substrate using the subsequent corresponding anodization voltage, and (f) removing the second UV-cured ink layer.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIG. 1A is a flowchart of steps in a method for anodizing refractory metals, and FIG. 1B shows corresponding cross-sectional views of a metal substrate at each of the process steps of FIG. 1A, in accordance with a first embodiment of the present invention;

FIG. 2A is a flowchart of steps in a method for anodizing refractory metals, and FIG. 2B shows corresponding cross-sectional views of a metal substrate at each of the process steps of FIG. 2A, in accordance with a second embodiment of the present invention;

FIG. 3 is a schematic diagram of one example of an anodic bath setup for anodizing metals;

FIG. 4 is a schematic diagram showing one method of aligning a metal substrate on the bed of a UV inkjet printer in a reproducible manner; and

FIG. 5 is a schematic diagram of a setup for “anodic painting.”

### DETAILED DESCRIPTION OF PREFERRED EMBODIMENTS

The following description is provided to enable a person of ordinary skill in the art to make and use the invention and sets forth the best modes contemplated by the inventor of carrying out his invention. Various modifications, however, will remain readily apparent to those skilled in the art, since the general principles of the present invention have been defined herein specifically to provide example embodiments.

Although photoresist masks may be used during an anodization process when one only wants to anodize predetermined portions of the metal, the spatial resolution that is achievable with photoresist masks is not ideal for creating high resolution multicolored line art images on refractory metals via anodization. Further, the use of photoresist masks does not lend itself to anodization of large scale areas. For example, using photoresist masks for photo milling and circuit board design limits the size of the substrate. The present invention provides a method of anodizing metals that enables the coloring of metals in a manner that allows for the creation of high resolution multicolored line art images on metal substrates, and that can accommodate metal substrates that are larger than the largest metal substrates that may be used if photoresist masks were used.

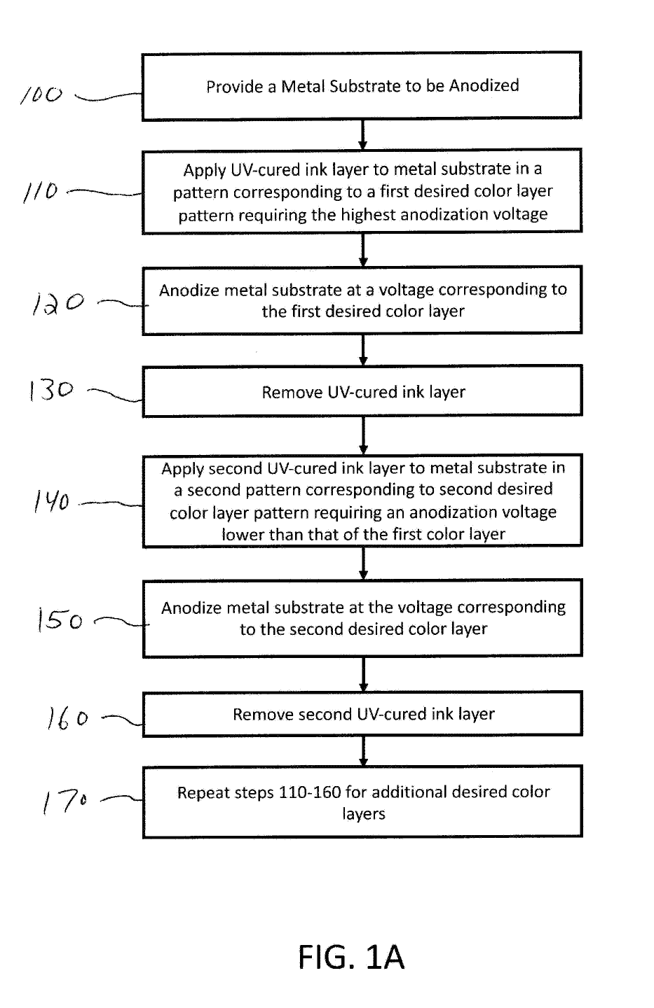

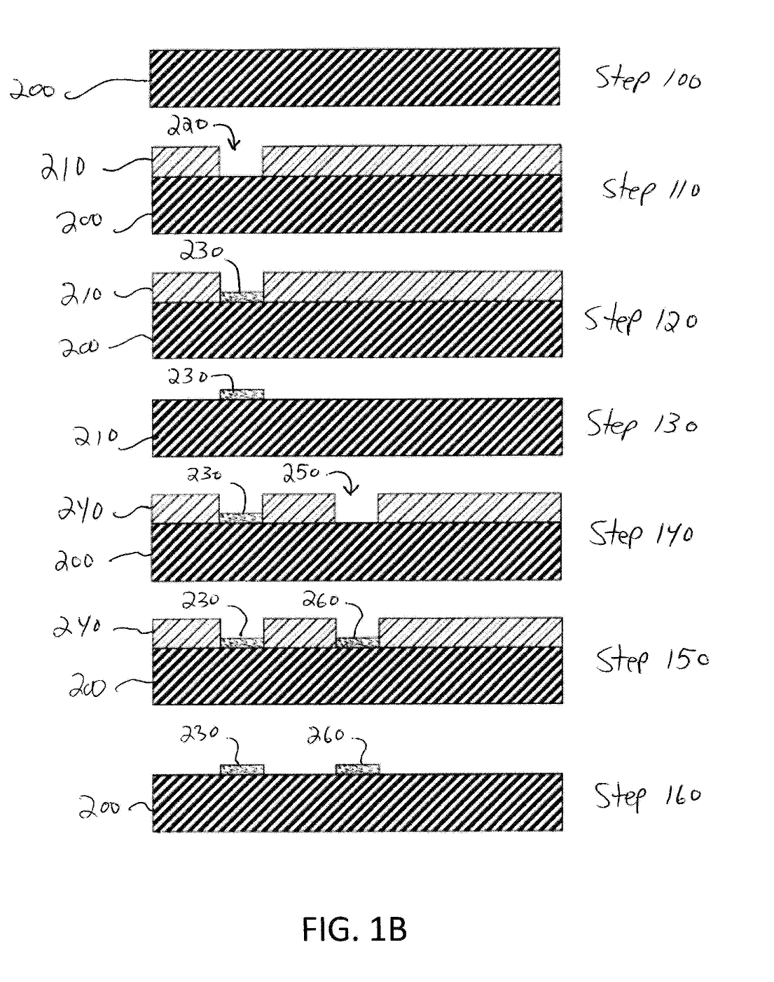

FIG. 1A is a flowchart of steps in a method for anodizing refractory metals, and FIG. 1B shows corresponding cross-sectional views of a metal substrate at each of the process steps of FIG. 1A, in accordance with a first embodiment of the present invention. In the embodiment of FIGS. 1A and 1B, the multiple oxide film layers (hereinafter also referred to as “color layer(s)”) are anodized based on the voltage required for each color layer. Specifically, the color layer requiring the highest anodization voltage is anodized first, followed by the color layer requiring the next highest voltage, and so forth, as will be explained in more detail below.

The method starts at step 100, where a metal substrate 200 is provided. The method of the present invention is particularly suitable for the anodization of refractory metals for creation of color layers and also for the creation multicolored line art images. Thus, the metal substrate is preferably any refractory metal substrate, suitably titanium, niobium, tantalum, hafnium, vanadium, molybdenum, tungsten, rhenium, chromium, zirconium, ruthenium, rhodium, osmium, iridium or any other refractory metal substrate on which color layers can be formed via anodization.

In general, the physical dimensions of the metal substrate 200 is limited only by the physical parameters of the UV inkjet printer that will be used to deposit the UV-curable ink during the anodization process. Thus, any size metal substrate 200 that can fit onto a UV inkjet printer for the deposition of UV-curable ink can be used while still falling within the scope of the present invention.

At step 110, a UV-cured ink layer 210 is deposited onto the metal substrate 200 in a pattern that corresponds to a first desired color pattern requiring the highest anodization voltage. The areas 220 on the metal substrate 200 where one wants to have the first color layer anodized are not covered by the UV-cured ink layer 210.

The UV-cured ink layer is preferably deposited using an inkjet printer equipped with UV-curable ink that is capable of curing the UV-curable ink as the ink is deposited. Suitable inkjet printers include the swissQprint Oryx LED flatbed inkjet printer and the Roland VersaUV® LEJ-640 flatbed UV-LED inkjet printer. However, any inkjet printer capable of dispensing and curing UV-curable ink onto a metal substrate can be used.

At step 120, the metal substrate 200 is anodized at a voltage corresponding to the first desired color layer. The anodization process yields the first color layer 230, which is an oxide layer having a thickness that produces the desired first color via optical interference effects.

At step 130, the UV-cured ink layer 210 is removed using any method known in the art, leaving the first color layer 230 on the areas of the metal substrate 200 that were not covered by the UV-ink layer 210. For example, the UV-ink layer 210 can be removed using a solvent, such as isopropyl alcohol.

At step 140, a second UV-cured ink layer 240 is deposited onto the metal substrate 200 in a second pattern that corresponds to a second desired color layer pattern requiring an anodization voltage lower than that required by the first color layer 230. The areas 250 on the metal substrate 200 where one wants to have the second color layer anodized are not covered by the second UV-cured ink layer 240. Further, because the anodization of the second color layer requires a lower voltage than that required for the first color layer 230, the first color layer 230 is preferably not covered by the second UV-cured ink layer 240. As a result, less UV-curable ink has to be utilized and less time is needed to deposit the second UV-cued ink layer 240 with the inkjet printer. Further, this will result in more seamless color integration.

For example, one advantage is what in printing parlance is known as “trapping”. In conventional digital print, to get precise alignment of multiple color layers, one or more color layers containing tiny dots or lines of color are slightly expanded to account for very small amounts of misalignment. Anodizing higher voltage color layers first accomplishes this same result. A higher voltage color layer is unaffected by exposure to lower voltage. Also, a higher voltage color layer is thicker than a lower voltage color layer. One can always change a lower voltage color layer to a higher voltage color layer but never change a higher voltage color layer to a lower voltage color layer, unless you mechanically or chemically do so.

At step 150, the metal substrate 200 is anodized at a voltage corresponding to the second desired color layer. The anodization process yields the second color layer 260, which is an oxide layer having a thickness that produces the desired second color via optical interference effects. At step 160, the second UV-cured ink layer 240 is removed, leaving the first color layer 230 and the second color layer 260.

At step 170, if additional color layers are desired, then steps 110-160 are repeated for each additional color layer that is desired, as long as each additional color layer requires a lower anodization voltage than all of the preceding color layers. In this way, the preceding color layers do not need to be covered by the subsequent UV-curable ink layers used to establish the patterns for the additional color layers.

Although the method described above and illustrated in FIGS. 1A and 1B preferably anodizes the multiple color layers in order of decreasing voltage requirements for each color layer, the multiple color layers can be anodized in random order without consideration of the voltage requirements for each color layer, as will be described in more detail below.

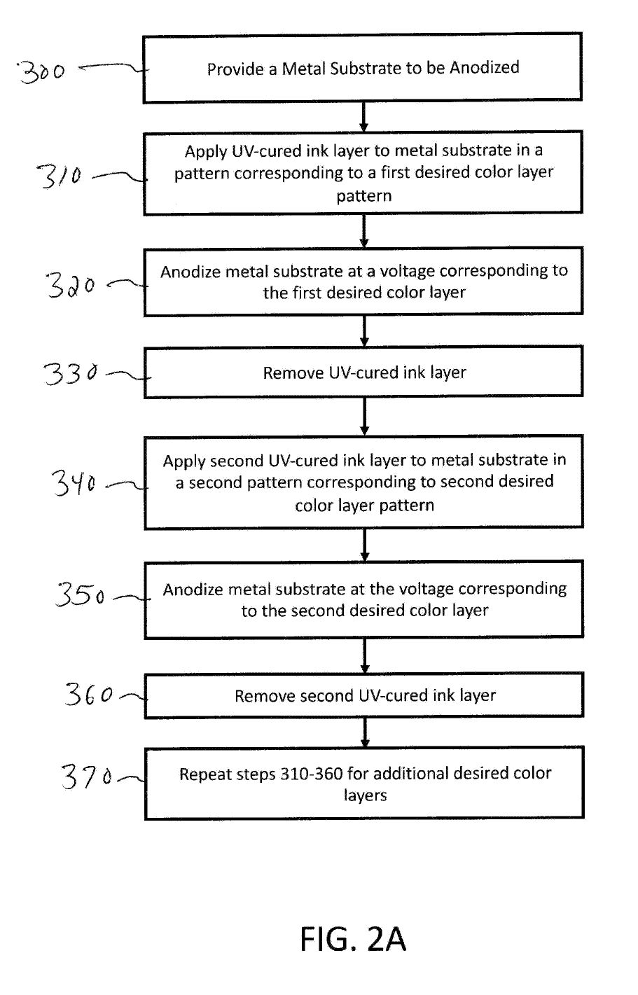

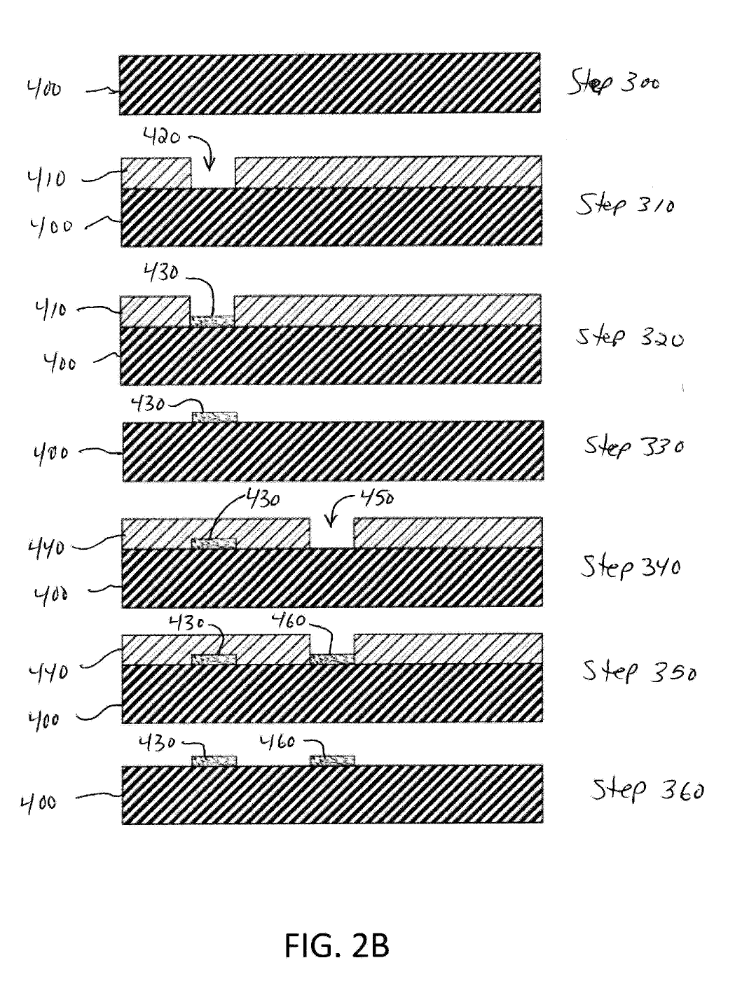

FIG. 2A is a flowchart of steps in a method for anodizing refractory metals, and FIG. 2B shows corresponding cross-sectional views of a metal substrate at each of the process steps of FIG. 2A, in accordance with a second embodiment of the present invention in which the order in which color layers are anodized does not necessarily depend on the voltage requirements for each color layer.

The method starts at step 300, where a metal substrate 400, preferably a refractory metal substrate, is provided. As discussed above, the physical dimensions of the metal substrate 200 is only limited by the physical parameters of the UV inkjet printer that will be used to deposit the UV-curable ink during the anodization process. Thus, any size metal substrate 200 that can fit onto a UV inkjet printer for the deposition of UV-curable ink can be used while still falling within the scope of the present invention.

At step 310, a UV-cured ink layer 410 is deposited onto the metal substrate 400 in a pattern that corresponds to a first desired color pattern. The areas 220 on the metal substrate 400 where one wants to have the first color layer anodized are not covered by the UV-cured ink layer 410. Further, although in the embodiments of FIGS. 1A and 1B the color layer requiring the highest anodization voltage is patterned and anodized first, in this embodiment it does not matter in what order the color layers are patterned and anodized.

At step 320, the metal substrate 400 is anodized at a voltage corresponding to the first desired color layer. The anodization process yields the first color layer 430, which is an oxide layer having a thickness that produces the desired first color via optical interference effects.

At step 330, the UV-cured ink layer 410 is removed using any method known in the art, leaving the first color layer 430 on the areas of the metal substrate 400 that were not covered by the UV-ink layer 410. As discussed above, the UV-ink layer 410 can be removed using a solvent, such as isopropyl alcohol.

At step 340, a second UV-cured ink layer 440 is deposited onto the metal substrate 400 in a second pattern that corresponds to a second desired color layer pattern. The areas 450 on the metal substrate 400 where one wants to have the second color layer anodized are not covered by the second UV-cured ink layer 240. As discussed above, in this embodiment it does not matter in what order the color layers are patterned and anodized. Thus, in this embodiment, the first color layer 430 is preferably covered by the second UV-cured ink layer 440. As a result, any type of color layer can be patterned and anodized as the second color layer, regardless of the anodization voltage required for the second color layer because the first color layer 430 will not be affected by the second anodization voltage as a result of it being covered by the second UV-cured ink layer 440.

At step 350, the metal substrate 400 is anodized at a voltage corresponding to the second desired color layer. The anodization process yields the second color layer 460, which is an oxide layer having a thickness that produces the desired second color via optical interference effects. At step 360, the second UV-cured ink layer 240 is removed, leaving the first color layer 230 and the second color layer 260.

At step 370, if additional color layers are desired, then steps 310-360 are repeated for each additional color layer that is desired in whatever order desired, regardless of the anodization voltage required for each subsequent color layer.

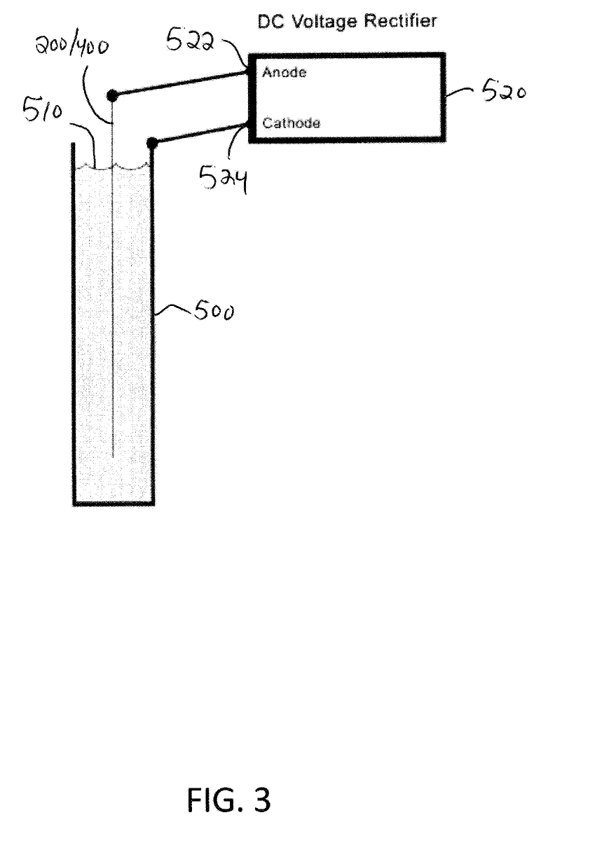

The anodization of the metal substrates 200 and 400 can be accomplished using any method and system known in the art for anodizing metals. FIG. 3 is a schematic diagram of one example of an anodic bath setup for anodizing metals. The setup shown in FIG. 3 includes a container 500 for holding the electrolytic solution 510. The container 500 is suitably made of a conductive material, such as stainless steel, or an insulating material, such as polyethylene, lined with a conductor, such as stainless steel.

A voltage generator, preferably a DC voltage rectifier 520, is used to supply the anodization voltage. The anode 522 of the rectifier 520 is connected to the metal substrate 200/400 being anodized, and the cathode 524 of the rectifier 520 is connected to either the wall of container 500 (if the container 500 is made of a conductive material) or to the conductive lining on the inside wall of the container 500 (if the container 500 is made of an insulating material). The metal substrate 200/400 is suspended in the electrolytic solution 510 while a voltage is applied using the rectifier 520.

The use of an inkjet printer to deposit the UV-cured ink layers 210, 240, 410 and 440 allows for color layer patterns with much higher spatial resolution that one can achieve with traditional photoresist-based masks. For example, most commercially available UV inkjet flatbed printers that can be used to deposit and cure UV-curable ink can deposit the UV-curable ink at resolutions as high as 1,340 dots per inch (dpi), whereas the highest spatial resolutions achievable using traditional photoresist-based masking techniques is approximately 80 dpi. Thus, the methods of the present invention can be used to create very detailed, high resolution multicolored line art images on refractory metals which were not possible to create using traditional photoresist-based masking techniques.

Further, a UV inkjet printer allows one to slightly expand or contract the print matrix of lines, dots, mezzotints, etc. Because the resolution of typical UV inkjet printers is so high and is a digital media, an artist or printer knowledgeable in the field of digital print would readily appreciate the ability to maintain alignment between color layers over a large area, especially since there may be many more color layers than might normally be used in conventional printing. For example, if the intended resolution of the image is 600 dpi, on the second and subsequent color layers the dot matrix could be expanded by making each dot slightly larger. This may be useful in revealing or capturing any unwanted alignment issues.

Although the embodiment of FIGS. 1A and 1B is used for patterning and anodizing successive color layers in decreasing order of anodization voltage required for each color layer, and the embodiment FIGS. 2A and 2B does not require any particular order of patterning and anodizing the color layers, a combination of the two methods can be used while still falling within the scope of the present invention.

For example, one can initially use the embodiment of FIGS. 1A and 1B to pattern and anodize a predetermined number and types of color layers in decreasing order of required anodization voltage. However, if one then decides to pattern and anodize an additional color layer with an anodization voltage greater than the anodization voltage of any of the color layers previously anodized, then one can use the embodiment of FIGS. 2A and 2B to pattern and anodize that additional color layer. In other words, if one needs to pattern and anodize a color layer that has a higher anodization voltage than previously anodized color layers, then the previously anodized color layers that have anodization voltages lower than the anodization voltage of the color layer being presently patterned and anodized should be covered by the UV-curable ink layer being used to pattern the present color layer.

As described above in connection with the embodiment of FIGS. 1A and 1B and the embodiment of FIGS. 2A and 2B, the process generally involves: (1) applying a UV-curable ink layer to the metal substrate 200/400; (2) removing the metal substrate 200/400 from the UV inkjet printer in order to anodize the substrate 200/400; (3) removing the UV-curable ink layer from the metal substrate 200/400; and (4) placing the metal substrate 200/400 back onto the UV inkjet printer in order to apply another UV-curable ink layer for patterning the next color layer. Thus, precise and reproducible alignment of the metal substrate 200/400 on the UV inkjet printer is needed so that UV-curable ink 240/440 can be applied to the precise areas needed on the metal substrate 200/400 even after the metal substrate 200/400 has been removed from and placed back on the UV inkjet printer.

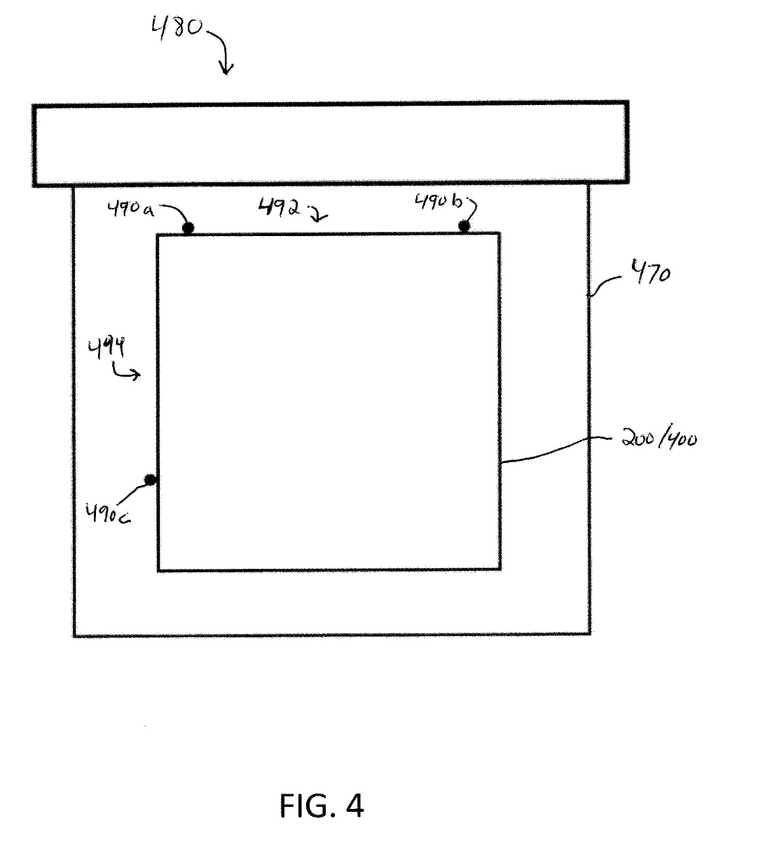

FIG. 4 is a schematic diagram showing one method of aligning a metal substrate 200/400 on the bed 470 of a UV inkjet printer 480 in a reproducible manner Pins 490a-490c are attached to two edges of the metal substrate 200/400. Specifically, two pins 490a and 490b one edge 492 of the metal substrate 200/400 and one pin 490c on an adjacent edge 494 of the metal substrate 200/400. The pins 490a-490c are then received by corresponding perforations/holes (not shown) formed on the bed of the UV inkjet printer 480. It should be appreciated that any other method known in the art for the reproducible alignment of a substrate on a UV inkjet printer could also be used.

Additional process options can be utilized to create creative effects in multicolored line art:

### Etching

Any portion of previously anodized color layer may be removed chemically to eliminate all or a portion of the anodized color layer from the substrate. This may be done by depositing a UV-curable ink layer on all areas except the portion of the anodized color layer that one wants to remove chemically, and using any method known in the art for chemical etching.

### Gradients

Referring to FIG. 3, any area not covered by a UV-curable ink layer may be colored anodized through a range of colors with seamless transitions by gradually removing the metal substrate 200/400 from the electrolytic solution 510 while increasing the anodization voltage. This can only be done by going from low to high voltage color layers. It is possible to transition through very narrow or broad ranges of adjacent colors or from lowest to highest voltage colors using this technique.

### Anodic Painting

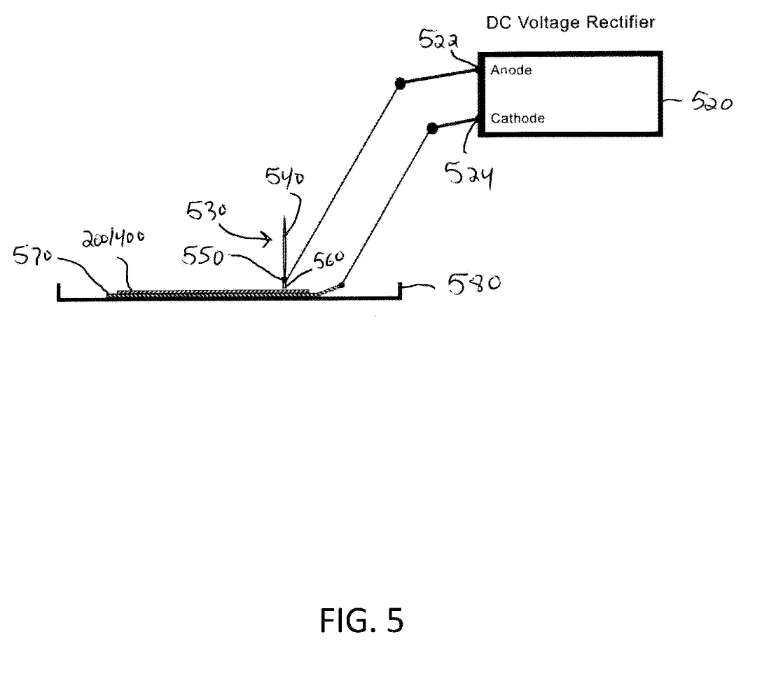

FIG. 5 is a schematic diagram of a setup for “anodic painting.” Any area not covered by a UV-curable ink layer may be color anodized by attaching the anode 522 of the rectifier 520 to a “painting” tool 530, which is suitably a piece of metal covered with an electrically inert material. In the example shown in FIG. 4, a painter's brush 530 is used with a handle 540 made of an electrically inert material, such as plastic or wood. A metal ring 550 is connected to the anode 522, and bristles 560 that are made of an electrically inert material contact the metal ring 560. Alternatively, a piece of metal covered by an electrically inert sponge material can be used in place of the metal ring 550 and bristles 560.

The metal substrate to be anodized 200/400 is placed on top of a conductor 570, such as stainless steel or other metal, or an insulating material, such as polyethylene, lined with a conductor 570, such as stainless steel. The conductor 570 is connected to the cathode 524 of the rectifier 520. To color anodize the areas on the metal substrate 200/400 not covered by a UV-curable ink layer via “painting,” the bristles 560 are dipped in an electrolytic solution (not shown) and the bristles soaked in the electrolytic solution are placed in contact with the exposed metal substrate areas that one wants to color anodize, similar to how one would paint a surface. The color characteristics of the color layer that is anodized using this method will depend, at least in part, on the voltage setting on rectifier 520, and on how often and how long the bristles 560 contact the exposed areas of the metal substrate 200/400.

The conductor 570 and metal substrate 200/400 may be optionally placed inside a container 580 that is made of an electrically insulating (inert) material, such as plastic, and a sufficient amount of electrolytic solution (not shown) may be placed in the container 580 to cover the conductor 570 and metal substrate 200/400 in order to aid the “anodic painting” process. This will result in different color effects that one would otherwise get without the submerging the conductor 570 and metal substrate 200/400 in electrolytic solution.

As discussed above, although the setup shown in FIG. 5 uses bristles 560 as the electrically inert material that is dipped in electrolytic solution and used to “paint” the color layers, a sponge material can be used in place of the bristles 560. This will produce different color layer effects than one would get using bristles 560. In general, any type and shape of electrically inert material can be used to “paint” the color layers via anodization, depending on the type of color layer effects one wants.

The foregoing embodiments and advantages are merely exemplary, and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. Various changes may be made without departing from the spirit and scope of the invention, as defined in the following claims.

What is claimed is:

1. A method of creating at least two color layers on a refractory metal substrate (“substrate”), comprising:
(a) applying a UV-cured ink layer to the substrate in a predetermined pattern corresponding to a desired pattern for a desired color layer, wherein the desired color layer requires a corresponding anodization voltage;
(b) anodizing the substrate using the corresponding anodization voltage to create the desired color layer on the substrate;
(c) removing the UV-cured ink layer;
(d) applying a subsequent UV-cured ink layer to the substrate in a predetermined pattern corresponding to a desired pattern for a subsequent desired color layer, wherein the subsequent desired color layer requires a subsequent corresponding anodization voltage that is lower than the anodization voltage used for the previous color layer;
(e) anodizing the substrate using the subsequent corresponding anodization voltage;
(f) removing the second UV-cured ink layer.

2. The method of claim 1, further comprising repeating steps (a)-(f) for additional desired color layers, wherein each subsequent color layer requires a corresponding anodization voltage that is lower than the anodization voltage used for all previous color layers.

3. The method of claim 1, wherein the substrate comprises at least one of titanium, niobium, tantalum, hafnium, vanadium, molybdenum, tungsten, rhenium, chromium, zirconium, ruthenium, rhodium, osmium and iridium.

4. The method of claim 1, wherein the UV-cured ink layers are applied to the substrate using an inkjet printer.

5. The method of claim 4, wherein the substrate comprises pins attached to perpendicular edges of the substrate for aligning the substrate on the inkjet printer.

6. The method of claim 4, wherein each UV-cured ink pattern is applied at a spatial resolution of at least 1,340 dpi.

7. The method of claim 1, further comprising:
applying a UV-ink layer on areas of the at least two color layers, except for areas of the at least two color layers that are to be removed;
applying a chemical etching compound to the substrate, wherein the chemical etching compound removes portions of the at least two color layers not covered by the UV-cured ink layer.

8. A multicolored line art image created using the method of claim 1.

9. A method of creating at least two color layers on a refractory metal substrate (“substrate”), comprising:
(a) applying a UV-cured ink layer to the substrate in a predetermined pattern corresponding to a desired pattern for a desired color layer, wherein the desired color layer requires a corresponding anodization voltage;
(b) anodizing the substrate using the corresponding anodization voltage to create the desired color layer on the substrate;
(c) removing the UV-cured ink layer;
(d) applying a subsequent UV-cured ink layer to the substrate in a predetermined pattern corresponding to a desired pattern for a subsequent desired color layer, wherein the subsequent desired color layer requires a subsequent corresponding anodization voltage that is lower than the anodization voltage used for the previous color layer and wherein the subsequent UV-cured ink layer is also applied so as to cover the previously created color layer;
(e) anodizing the substrate using the subsequent corresponding anodization voltage;
(f) removing the second UV-cured ink layer.

10. The method of claim 9, further comprising repeating steps (a)-(f) for additional desired color layers, wherein each subsequent UV-cured ink layer is applied so as to cover all previously created color layers.

11. The method of claim 9, wherein the substrate comprises at least one of titanium, niobium, tantalum, hafnium, vanadium, molybdenum, tungsten, rhenium, chromium, zirconium, ruthenium, rhodium, osmium and iridium.

12. The method of claim 9, wherein the UV-cured ink layers are applied to the substrate using an inkjet printer.

13. The method of claim 12, wherein the substrate comprises pins attached to perpendicular edges of the substrate for aligning the substrate on the inkjet printer.

14. The method of claim 12, wherein each UV-cured ink pattern is applied at a spatial resolution of at least 1,340 dpi.

15. The method of claim 9, further comprising:
applying a UV-ink layer on areas of the at least two color layers, except for areas of the at least two color layers that are to be removed;
applying a chemical etching compound to the substrate, wherein the chemical etching compound removes portions of the at least two color layers not covered by the UV-cured ink layer.

16. The method of claim 9, wherein the substrate is anodized by immersing it in an anodic bath.

17. The method of claim 16, wherein the anodic bath comprises:
a container for holding an electrolytic solution; and
a DC voltage generator, wherein the DC voltage generator comprises an anode electrically connected to the substrate and a cathode electrically connected to the electrolytic solution.

18. The method of claim 17, wherein at least one color layer is created by:
immersing the substrate in the electrolytic solution;
applying a voltage using the DC voltage generator;
gradually removing the substrate from the electrolytic solution while the applied voltage is varied using the DC voltage generator.

19. A multicolored line art image created using the method of claim 9.

20. The method of claim 9, wherein the substrate is anodized by:
connecting a tool to the anode of a DC voltage generator;
at least partially immersing the substrate in an electrolytic solution;
electrically connecting the cathode of the DC voltage generator to the electrolytic solution;
dipping the tool in electrolytic solution; and
placing the tool in sufficient proximity to the areas of the substrate not covered by the UV-cure ink layer while a voltage is applied by the voltage generator so as to create the desired color layer.
